(19) United States
(12) Patent Application Publication
(10) Pub. No.: US 2025/0309161 A1
(43) Pub. Date: Oct. 2, 2025

(54) SEMICONDUCTOR DEVICE AND METHODS OF MANUFACTURING

(71) Applicant: Taiwan Semiconductor Manufacturing Company, Ltd., Hsinchu (TW)

(72) Inventors: Fang-I CHIH, Hsinchu (TW); Chun-Wen HSIAO, Hsinchu (TW); Peng-Chung JANGJIAN, Hsinchu (TW)

(21) Appl. No.: 18/619,734

(22) Filed: Mar. 28, 2024

(51) Int. Cl. H01L 23/00

(52) U.S. Cl. CPC H01L 24/05; H01L 24/03; H01L 24/08; H01L 2224/0345; H01L 2224/03452; H01L 2224/03462; H01L 2224/03616; H01L 2224/05017; H01L 2224/08145; H01L 2924/3512

(57) ABSTRACT

Some implementations described herein provide a semiconductor device including conductive structures formed as part of a copper redistribution layer. Forming the conductive structures includes forming the conductive structures in a masking structure and performing a chemical/mechanical polishing process to planarize the conductive structures. Forming the conductive structures in the masking structure enables the conductive structures to have rounded footers and reduce stress concentrations within the semiconductor device relative to another semiconductor device using an aluminum copper redistribution layer. Additionally, planarizing the conductive structures reduces a rounding of surfaces of the conductive structures that join with interconnect structures to reduce a likelihood of bonding defects.

### BACKGROUND

A semiconductor device, such as a processor, a memory device, or another type of semiconductor device, may include one or more redistribution layers. A redistribution layer (RDL) is a thin layer of a conductive material that includes conductive traces and/or pads to redistribute conductive structures (e.g., bond pads and/or interconnects) of the semiconductor device on a different pattern, often to match routing and/or spacing requirements of external connection structures that connect to the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of a portion of an example semiconductor device described herein.

FIGS. 3A-3F are diagrams of an example implementation of forming a structure of a semiconductor device using an example chemical/mechanical planarization process described herein.

FIG. 4 is a diagram of an example semiconductor die package described herein.

FIG. 5 is a diagram of an example implementation described herein.

FIGS. 6A-6C are diagrams of data related to example implementations of a conductive structure described herein.

FIG. 7 is a diagram of example components one or more devices described herein.

FIGS. 8 and 9 are flowcharts of example processes associated with forming a semiconductor device using a chemical/mechanical planarization process described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a redistribution layer (RDL) includes conductive structures formed from an aluminum copper (AlCu) material. Forming the conductive structures may include using a sputtering process that causes abruptly angled footers that, in combination with a coefficient of thermal expansion of the AlCu material, induce stress concentrations that cause cracks and/or defects in the conductive structures. In other cases, the RDL includes a copper (Cu) material. Although using the Cu material may result in the conductive structures having rounded footers that alleviate such stress concentrations, variations in heights of the conductive structures may create variations in etching profiles that cause rounded surfaces at a top of the conductive structures. The rounded surfaces (e.g., rounded lands) may result in bonding defects between the conductive structures and interconnect structures that connect with the conductive structures. The bonding defects can decrease a quality and/or a reliability of a semiconductor device including the conductive structures formed using the RDL including the Cu material.

Some implementations described herein provide a semiconductor device including conductive structures formed as part of a Cu RDL. Forming the conductive structures includes forming the conductive structures in a masking structure and performing a chemical/mechanical polishing (CMP) process to planarize the conductive structures. Forming the conductive structures in the masking structure enables the conductive structures to have rounded footers and reduce stress concentrations within the semiconductor device relative to another semiconductor device using an AlCu RDL. Additionally, planarizing the conductive structures reduces a rounding of surfaces of the conductive structures that join with interconnect structures to reduce a likelihood of bonding defects.

In this way, a quality and/or a reliability of the semiconductor device is improved. By improving the quality and/or the reliability of the semiconductor device, an amount of resources used to support a market consuming the semiconductor device (e.g., raw materials, semiconductor manufacturing tools, labor, and/or computing resources) is reduced.

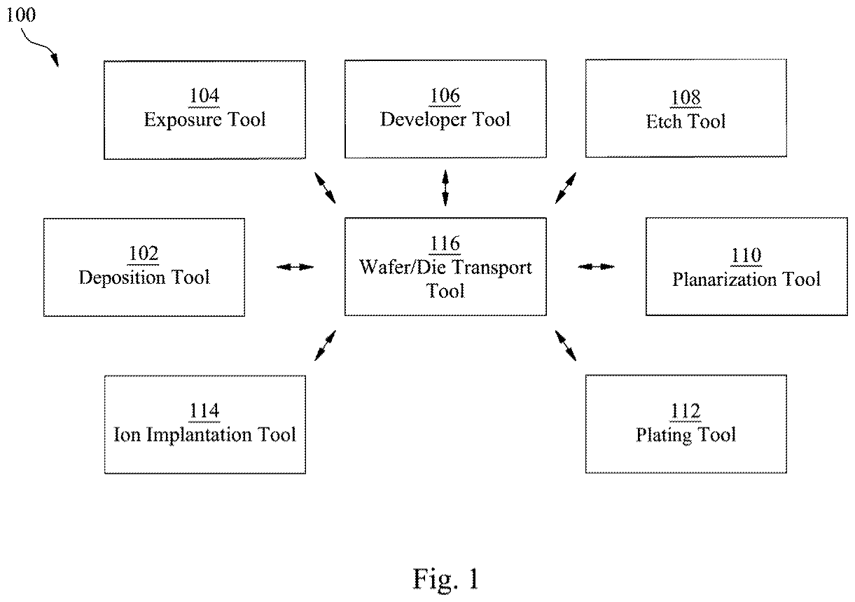

FIG. 1 is a diagram of an example environment 100 in which systems and/or methods described herein may be implemented. The example environment 100 includes semiconductor processing tools that can be used to form semiconductor structures and devices, such as a conductive structure as described herein.

As shown in FIG. 1, the environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 may include a chemical vapor deposition (CVD) tool, such as a plasma-enhanced CVD (PECVD) tool, a high-concentration plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or another type of exposure tool. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or another type of etch tool. In some implementations, the etch tool 108 includes a chamber that is filled with an etchant, and the substrate is placed in the chamber for a particular time period to remove particular amounts of one or more portions of the substrate. In some implementations, the etch tool 108 etches one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 includes a mobile robot, a robot arm, a tram or rail car, an overhead hoist transfer (OHT) vehicle, an automated material handling system (AMHS), and/or another type of tool that is used to transport wafers and/or dies between semiconductor processing tools 102-114 and/or to and from other locations such as a wafer rack, a storage room, or another location. In some implementations, the wafer/die transport tool 116 is a programmed tool to travel a particular path and/or may operate semi-autonomously or autonomously.

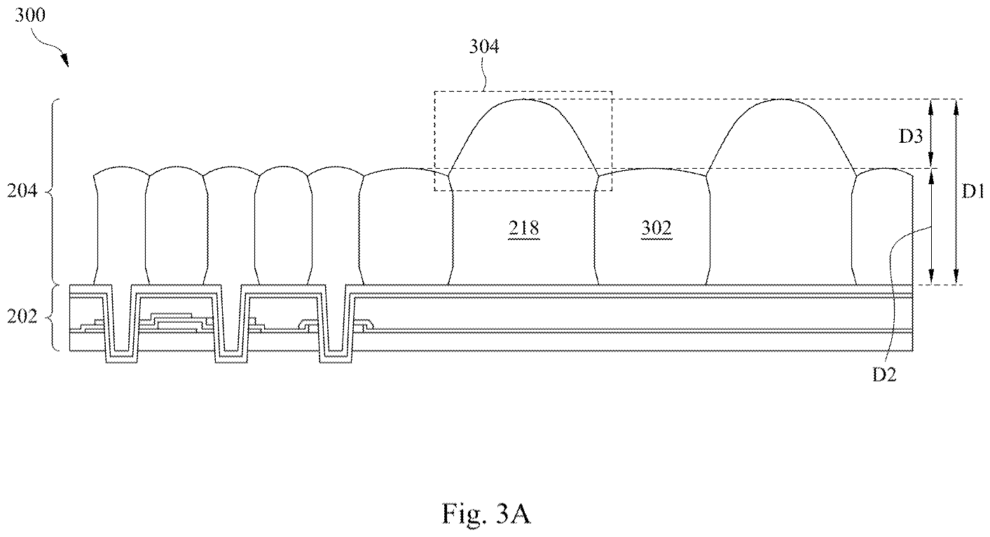

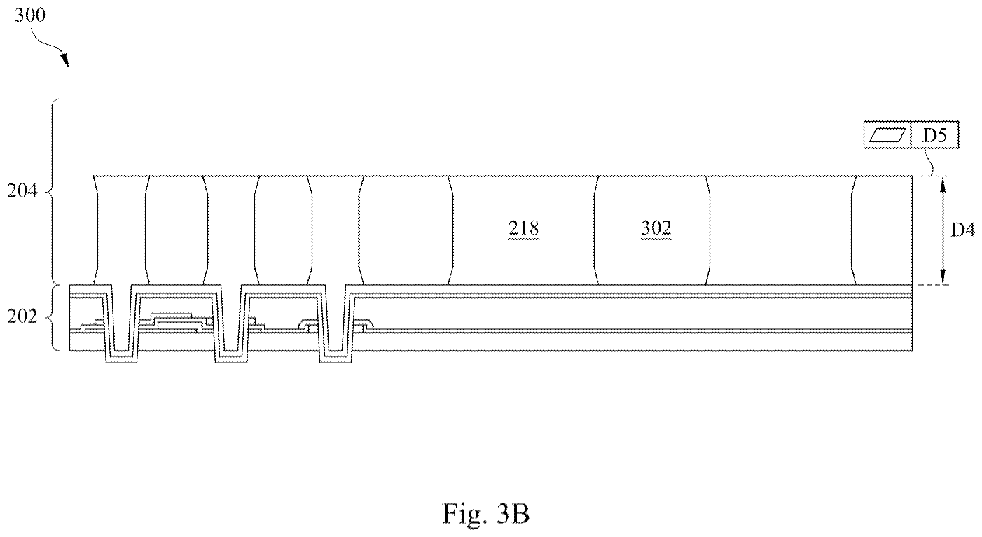

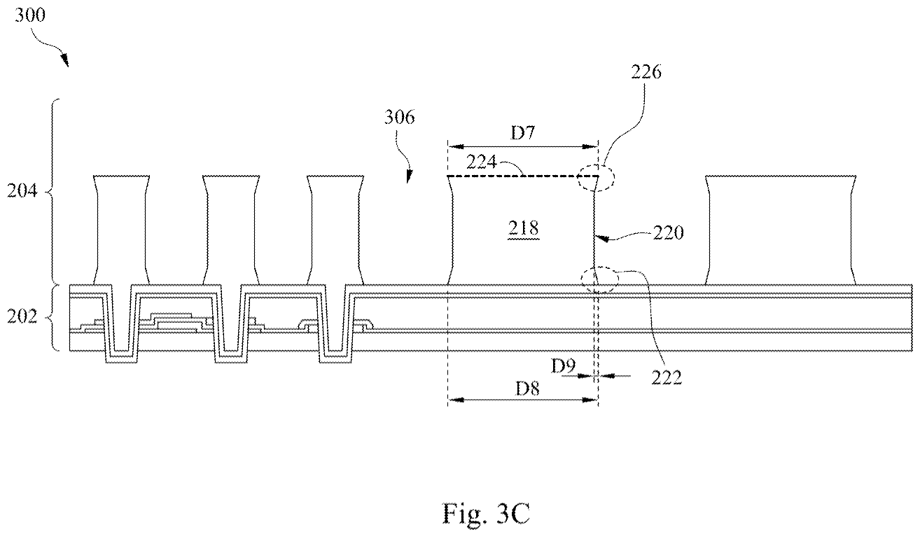

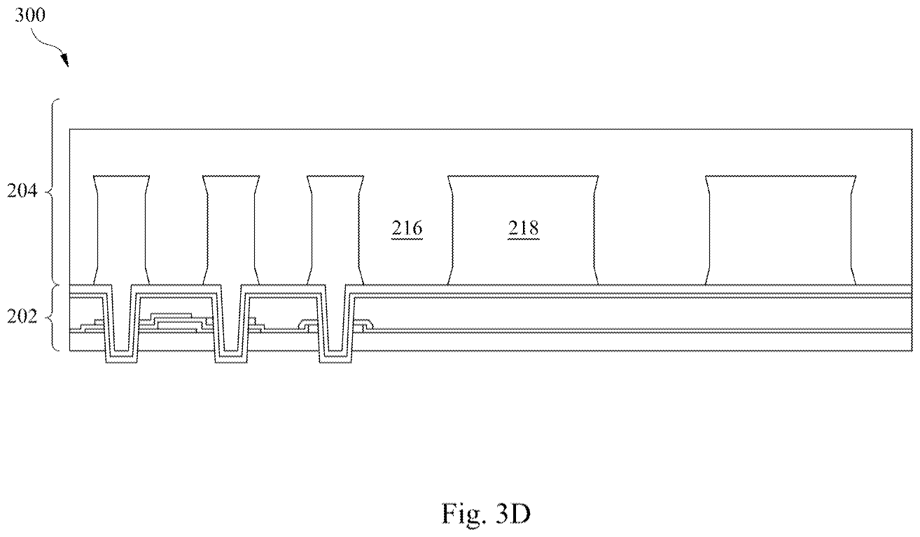

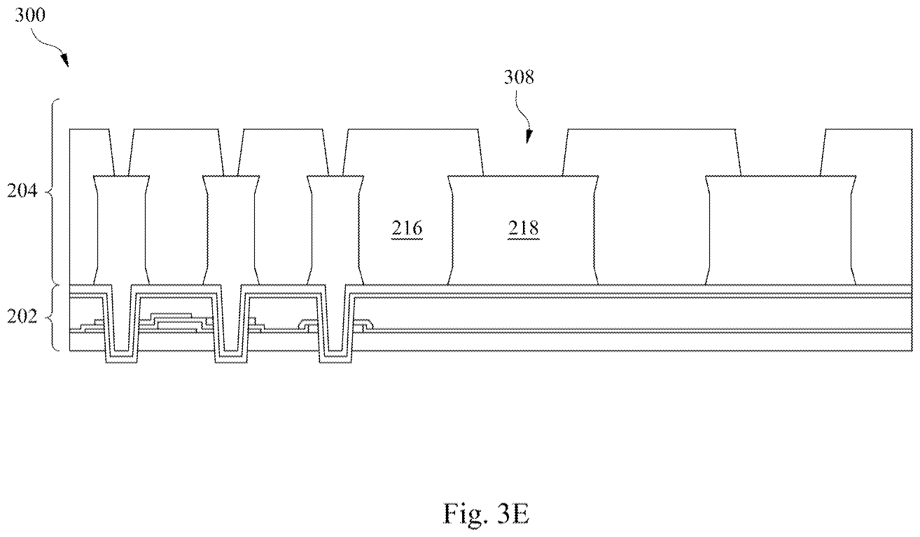

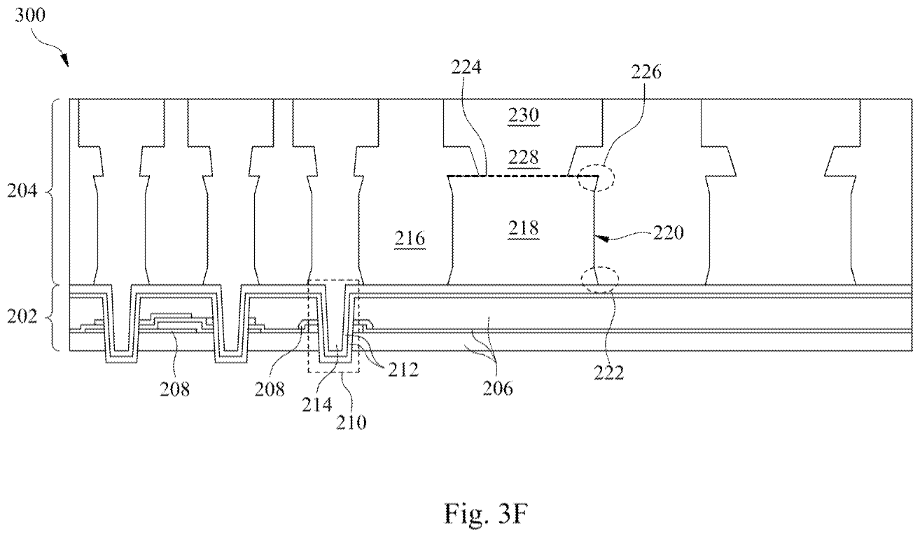

As described in greater detail in connection with FIGS. 3A-3F, one or more of the semiconductor processing tools 102-114 may perform a series of semiconductor manufacturing operations. The series of semiconductor manufacturing operations includes forming a masking layer. The series of semiconductor manufacturing operations includes forming, in openings of the masking layer, a conductive structure having a portion that extends above a top surface of the masking layer. The series of semiconductor manufacturing operations includes removing the portion that extends above the top surface to form an approximately planar, horizontal surface on the conductive structure. The series of semiconductor manufacturing operations includes removing the masking layer. The series of semiconductor manufacturing operations includes forming a dielectric layer over the conductive structure. The series of semiconductor manufacturing operations includes forming an interconnect structure that penetrates through the dielectric layer and connects with the approximately planar, horizontal surface of the conductive structure.

Additionally, or alternatively, the series of semiconductor manufacturing operations includes forming, in openings of a masking layer over a semiconductor die, conductive structures of a redistribution layer having different heights across the semiconductor die. The series of semiconductor manufacturing operations includes removing a portion of at least one of the conductive structures to reduce a variation in the different heights across the semiconductor die. The series of semiconductor manufacturing operations includes removing the masking layer. The series of semiconductor manufacturing operations includes forming a dielectric layer over the conductive structures. The series of semiconductor manufacturing operations includes forming interconnect structures that penetrate through the dielectric layer and connect with the conductive structures.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

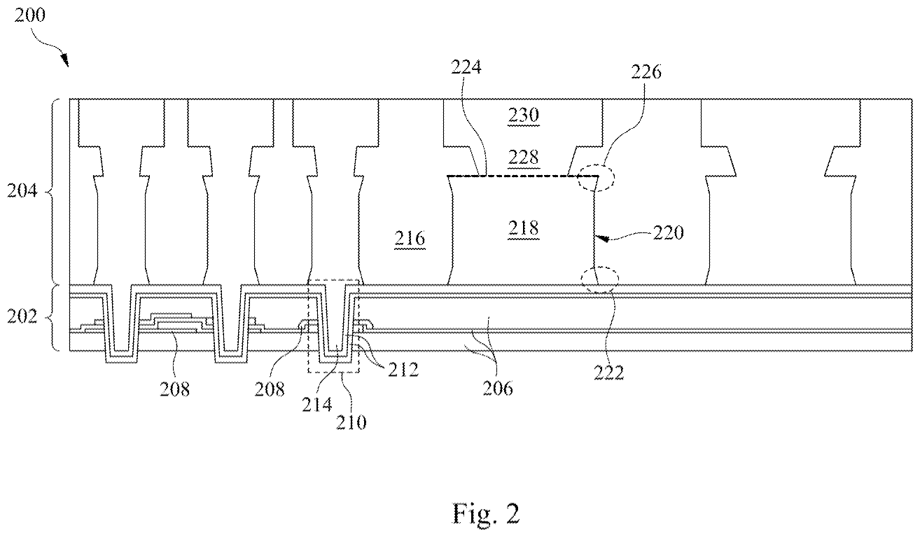

FIG. 2 is a diagram of a portion of an example semiconductor device 200 described herein. The semiconductor device 200 may include system on chip (SoC) device, a logic device such as a central processing unit (CPU) or a graphics processing unit (GPU), a memory device (e.g., a high bandwidth memory (HBM) device), and/or another type of semiconductor device that includes one or more transistor structures.

As shown in the side view of FIG. 2, the semiconductor device 200 may include a device region 202 and an interconnect region 204 above the device region 202. The device region 202 includes one or more dielectric layers 206. The dielectric layer(s) 206 may be over and/or on a substrate (e.g., a silicon substrate) and include a silicon nitride (SixN), an oxide (e.g., a silicon oxide (SiOx) and/or another oxide material), and/or another type of dielectric material.

Integrated circuitry 208 (e.g., integrated circuit devices) may be included in the dielectric layer(s) 206 in the device region 202. The integrated circuitry 208 may include semiconductor devices such as transistors (e.g., planar transistors, fin field effect transistors (finFETs), gate all around (GAA) transistors), pixel sensors, capacitors, resistors, inductors, photodetectors, transceivers, transmitters, receives, optical circuits, other types of semiconductor devices, and or metallization layers that connect the semiconductor devices.

In some implementations, the semiconductor device 200 includes one or more isolation structure(s) 210. The isolation structure(s) 210 may penetrate through the dielectric layer(s) 206 and include one or more liner layers 212. The liner layer(s) 212 may include a dielectric material such as a silicon nitride (SixN), an oxide (e.g., a silicon oxide (SiOx) and/or another oxide material), and/or another type of dielectric material. The isolation structure(s) 210 may electrically isolate one or more interconnect structure(s) 214 that extend into the dielectric layer(s) 206 and/or connect with the integrated circuitry 208.

The interconnect region 204 includes or more dielectric layer(s) 216 that are over and/or on the device region 202. In some implementations, the dielectric layer(s) 216 include an oxide (e.g., a silicon oxide (SiOx) and/or another oxide material), a borophosphosilicate glass (BPSG), and/or another type of dielectric material.

Within the dielectric layer(s) 216, a redistribution layer (RDL) that includes a conductive material may be used to form one or more conductive structures 218. Each of the conductive structure(s) 218 may include a vertically-oriented sidewall 220 having a concave-shaped surface that extends inwards towards a center of the conductive structure(s) 218. The conductive structure(s) 218 (e.g., the RDL) may include a conductive material such as copper (Cu), among other examples. In some implementations, one or more of the dielectric layer(s) 216 surrounds the conductive structure(s) 218.

As shown in FIG. 2, a rounded footer 222 may protrude laterally from the vertically-oriented sidewall 220 near a base of each of the conductive structure(s) 218. The rounded footer 222 may include a curvature to reduce stress concentration at a base of the conductive structure(s) 218 to improve a quality and/or a reliability of the semiconductor device 200. Furthermore, the dielectric layer(s) 216 conform to the vertically-oriented sidewall 220 (e.g., the concave-shaped surface of the vertically-oriented sidewall 220) and/or the rounded footer 222.

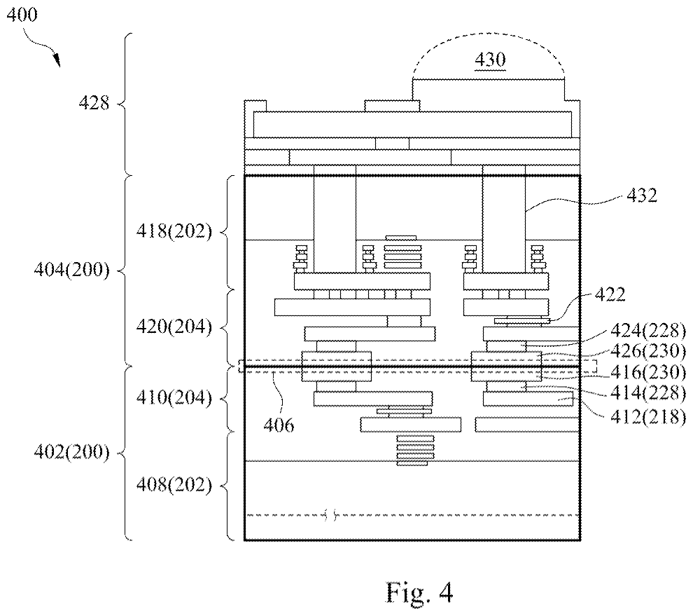

As further shown in FIG. 2, each of the conductive structure(s) 218 may include an approximately planar, horizontal surface 224. The approximately planar, horizontal surface 224 may intersect with the vertically-oriented sidewall 220 and form a sharp corner 226. As described in greater detail in connection with FIG. 3C, FIG. 4, and elsewhere herein, the sharp corner 226 may include an acute angle or an obtuse angle.

The semiconductor device 200 may further include one or more interconnect structures 228 (e.g., vertical interconnect access structures) that connect with the conductive structure(s) 218. The interconnect structure(s) 228 may include a conductive material such as copper (Cu), among other examples. The interconnect structure(s) 228 may connect (e.g., join or merge) with the conductive structure(s) 218 along a corresponding approximately planar, horizontal surface 224. As described in greater detail in connection with FIG. 3B and elsewhere herein, the approximately planar, horizontal surface 224 may provide a more robust connection with the interconnect structure(s) 228 to improve a quality and/or a reliability of the semiconductor device 200.

One or more bond pad structures 230 may be over and/or on the interconnect structure(s) 228. The bond pad structure(s) 230 may include a conductive material such as copper (Cu), among other examples. As described in greater detail in connection with FIG. 4, the bond pad structure(s) 230 may be used to join the semiconductor device 200 with another semiconductor device.

As described in connection with FIG. 2, and in some implementations, a device (e.g., the semiconductor device 200) includes a conductive structure (e.g., the conductive structure(s) 218) of a redistribution layer. The conductive structure includes a vertically-oriented sidewall (e.g., the vertically-oriented sidewall 220), a rounded footer (e.g., the rounded footer 222) protruding laterally from the vertically-oriented sidewall at a base of the conductive structure, and an approximately planar, horizontal surface (e.g., the approximately planar, horizontal surface 224) that forms a sharp corner (e.g., the sharp corner 226) with the vertically-oriented sidewall at a top of the conductive structure that is opposite the base. The device includes an interconnect structure (e.g., the interconnect structure(s) 228) that connects to the conductive structure along the approximately planar, horizontal surface.

As indicated above, FIG. 2 is provided as an example. Other examples may differ from what is described with regard to FIG. 2.

FIGS. 3A-3F are diagrams of an example implementation 300 of forming a semiconductor device (e.g., the semiconductor device 200) using an example chemical/mechanical planarization process described herein. Implementation 300 may include using one or more of the semiconductor processing tools 102-114 and/or the wafer/die transport tool 116 described in connection with FIG. 1.

As shown the side view of FIG. 3A, a masking layer 302 (e.g., a masking structure) is formed over and/or on the device region 202. In some cases, the masking layer 302 includes a photoresist material. In such a case, a deposition tool 102 may be used to dispense the photoresist material over and/or on the device region 202. An exposure tool 104 may be used to expose a pattern on the masking layer 302, and a developer tool 106 may be used to remove exposed photoresist material to form openings in the masking layer 302.

Alternatively, and in some cases, the masking layer 302 includes a hard mask material. In such a case, a pattern in a photoresist layer is used to etch the hard mask material to form the openings in the masking layer 302. In these implementations, a deposition tool 102 may be used to form the photoresist layer on the and/or over the device region 202. An exposure tool 104 may be used to expose the photoresist layer to a radiation source to pattern the photoresist layer. A developer tool 106 may be used to develop and remove portions of the photoresist layer to expose the pattern. The etch tool 108 may be used to etch the masking layer 302 based on the pattern to form the openings in the masking layer 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the masking layer 302 based on a pattern.

As further shown in FIG. 3A, the conductive structure(s) 218 are formed in the openings of the masking layer 302. To form the conductive structure(s) 218, a deposition tool 102 and/or a plating tool 112 may be used to deposit the conductive structure(s) 218 using a CVD technique, a PVD technique, an ALD technique, an electroplating technique, another deposition technique described above in connection with FIG. 1, and/or another suitable deposition technique. The conductive structure(s) 218 may be deposited in one or more deposition operations. In some implementations, a seed layer is first deposited, and the conductive structure(s) 218 are deposited on the seed layer.

As further shown in FIG. 3A and based on a width of an opening in the masking layer 302, heights of the conductive structure(s) 218 may vary. As an example, the conductive structure 218a may have a portion 304 that extends above a top surface of the masking layer 302, causing one or more of the conductive structure(s) 218 to have a height D1 that is greater than a height D2 of the masking layer 302. In some implementations, a difference D3 in heights exists across the conductive structure(s) 218 within an area of the semiconductor device 200.

Turning to FIG. 3B, a planarization operation is performed to planarize the conductive structure(s) 218 and reduce variations in heights (e.g., reduce the difference D3). To planarize the conductive structure(s) 218, a planarization tool 110 may be used to perform a chemical/mechanical planarization operation. As an example, and in a case where the conductive structure(s) 218 include a copper material, a planarization tool 110 may use a copper slurry with a polishing pad having a shore hardness (durometer) of approximately D<50 and a porosity of greater than approximately 25%. However, other slurries and/or polishing pad properties are within the scope of the present disclosure.

In some implementations, the planarization operation includes removing portions of the masking layer 302 (e.g., the planarization operation stops on or within the masking layer 302). Alternatively, and in some implementations, the planarization operation does not include removing portions of the masking layer (e.g., the planarization operation stops above the masking layer 302).

After the planarization operation, the conductive structure(s) 218 may have a height D4 that is included in a range of approximately 2 microns (μm) to approximately 7 μm. Additionally, or alternatively the conductive structure(s) 218 may have a planarity D5 (e.g., a variation in heights within a semiconductor die including the conductive structure(s) 218) that is less than approximately 100 nanometers (nm). If the planarity D5 is greater than approximately 100 nm, the planarization operation may be incomplete and rounded surfaces of one or more of the conductive structure(s) 218 may exist, thereby reducing a quality and/or a reliability (e.g., a robustness) of interfaces (e.g., fused regions) subsequently formed between the conductive structure(s) 218 and interconnect structures (e.g., the interconnect structure(s) 228). However, other values and ranges for the height D4 and/or the planarity D5 are within the scope of the present disclosure.

Turning to FIG. 3C, cavities 306 are formed between the conductive structure(s) 218 by removing the masking layer 302. To remove the masking layer 302, a photoresist removal tool may be used to remove the masking layer 302 using a chemical stripper, plasma ashing, and/or another technique. Alternatively, an etch tool 108 may be used to remove the masking layer 302 using a plasma etch, a wet chemical etch, and/or another type of etch technique.

As shown in FIG. 3C, the conductive structure 218 includes the rounded footer 222, the vertically-oriented sidewall 220, the approximately planar, horizontal surface 224, and the sharp corner 226. The conductive structure(s) 218 may have one or more dimensional properties. For example, a width D7 at top of one or more of the conductive structure(s) 218 may be included in a range of approximately 1.5 μm to approximately 100 μm. However, other values and ranges for the width D7 are within the scope of the present disclosure.

Additionally, or alternatively, a width D8 near bottom of one or more of the conductive structure(s) 218 may be greater than the width D7. If the width is D8 is less than or equal to the width D7, the planarization operation may be incomplete and a rounded surface at a top of the conductive structure(s) 218 may exist, thereby reducing a reliability of an interface subsequently formed between the conductive structure(s) 218 and the interconnect structure(s) 228.

Additionally, or alternatively, the rounded footer 222 may protrude laterally from the vertically-oriented sidewall 220 a distance D9 that is included in a range of approximately 0.1 μm to approximately 100 μm. However, other values and ranges for the width D7 are within the scope of the present disclosure.

Turning to FIG. 3D, the dielectric layer(s) 216 are formed over and/or on the conductive structure(s) 218. A deposition tool 102 may be used to deposit the dielectric layer(s) 216 using a PVD technique, an ALD technique, a CVD technique, an oxidation technique, another type of deposition technique described in connection with FIG. 1, and/or another suitable deposition technique. The dielectric layer(s) 216 may be deposited in one or more deposition operations. In some implementations, a planarization tool 110 may be used to planarize the dielectric layer(s) 216 after deposition of the dielectric layer(s) 216.

Turning to FIG. 3E, cavities 308 are formed in the dielectric layer(s) 216 to expose the conductive structure(s) 218. In some implementations, a pattern in a photoresist layer is used to etch the dielectric layer(s) 216 to form the cavities 308. In these implementations, a deposition tool 102 may be used to form the photoresist layer on the dielectric layer(s) 216. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer(s) 216 based on the pattern to form the cavities 308 in the dielectric layer(s) 216. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer(s) 216 based on a pattern.

Turning to FIG. 3F, additional dielectric layer(s) 216 are formed. A deposition tool 102 may be used to deposit the dielectric layer(s) 216 using a PVD technique, an ALD technique, a CVD technique, an oxidation technique, another type of deposition technique described in connection with FIG. 1, and/or another suitable deposition technique. The dielectric layer(s) 216 may be deposited in one or more deposition operations. In some implementations, a planarization tool 110 may be used to planarize the dielectric layer(s) 216 after deposition of the dielectric layer(s) 216.

Furthermore, bond pad structure(s) 230 are formed over and/or on the interconnect structure(s) 228. In some implementations, a pattern in a photoresist layer is used to etch the dielectric layer(s) 216 to form the cavities that expose the interconnect structure(s) 228. In these implementations, a deposition tool 102 may be used to form the photoresist layer on the dielectric layer(s) 216. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer(s) 216 based on the pattern to form the cavities and expose the interconnect structure(s) 228. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). The bond pad structure(s) 230 may be formed in the cavities. To form the bond pad structure(s) 230, a deposition tool 102 and/or a plating tool 112 may be used to deposit the bond pad structure(s) 230 using a CVD technique, a PVD technique, an ALD technique, an electroplating technique, another deposition technique described above in connection with FIG. 1, and/or another suitable deposition technique. The bond pad structure(s) 230 may be deposited in one or more deposition operations. In some implementations, a seed layer is first deposited, and the bond pad structure(s) 230 are deposited on the seed layer. In some implementations, a planarization tool 110 may be used to planarize the bond pad structure(s) 230 after deposition of the bond pad structure(s) 230.

As indicated above, FIGS. 3A-3F are provided as an example. Other examples may differ from what is described with regard to FIGS. 3A-3F.

FIG. 4 is a diagram of an example semiconductor die package 400 described herein. The semiconductor die package 400 may correspond to a wafer-on-wafer (WoW) semiconductor die package and have two semiconductor dies bonded using bond pad structures (e.g., the bond pad structure(s) 230) described herein.

As shown in the side view of FIG. 4, a semiconductor die 402 (e.g., an implementation of the semiconductor device 200) is joined with a semiconductor die 404 along a bond interface region 406. The semiconductor die 402 includes a device region 408 (e.g., an implementation of the device region 202) and an interconnect region 410 (e.g., an implementation of the interconnect region 204). Within the interconnect region 410, the semiconductor die 402 includes redistribution layer structure(s) 412 (e.g., an implementation of the conductive structure(s) 218), interconnect structures(s) 414 (e.g., an implementation of the interconnect structure(s) 228), and bond pad structure(s) 416 (e.g., an implementation of the bond pad structure(s) 230).

The semiconductor die 404 (e.g., an implementation of the semiconductor device 200) includes a device region 418 (e.g., an implementation of the device region 202) and an interconnect region 420 (e.g., an implementation of the interconnect region 204). Within the interconnect region 420, the semiconductor die 404 includes redistribution layer structure(s) 422 (e.g., an implementation of the conductive structure(s) 218), interconnect structures(s) 424 (e.g., an implementation of the interconnect structure(s) 228), and bond pad structure(s) 426 (e.g., an implementation of the bond pad structure(s) 230).

A bumping region 428 may be on and/or over the semiconductor die 404, and include one or more bumps 430 (e.g., solder bumps and/or pillar structures) that are made from a conductive material (e.g., copper (Cu), a tin silver copper alloy (SAC), or a tin copper nickel alloy (SN100C), among other examples) that is suitable for soldering to an interface board and communicating electrical signals. Such electrical signals may be routed between the semiconductor die 402, the semiconductor die 404, and to or from the bumps 430 using through silicon via (TSV) interconnect structures 432 included in the semiconductor die 402 and/or the semiconductor die 404.

As shown in FIG. 4, the bond pad structure(s) 416 and the bond pad structure(s) 426 may be joined using a eutectic bonding process. Further, and as described in connection with FIGS. 3A-3F, interfaces between the interconnect structure(s) 414/424 and the bond pad structure(s) 416/426 may be approximately horizontal, planar interfaces that improve an overall quality and/or reliability of the semiconductor die package 400.

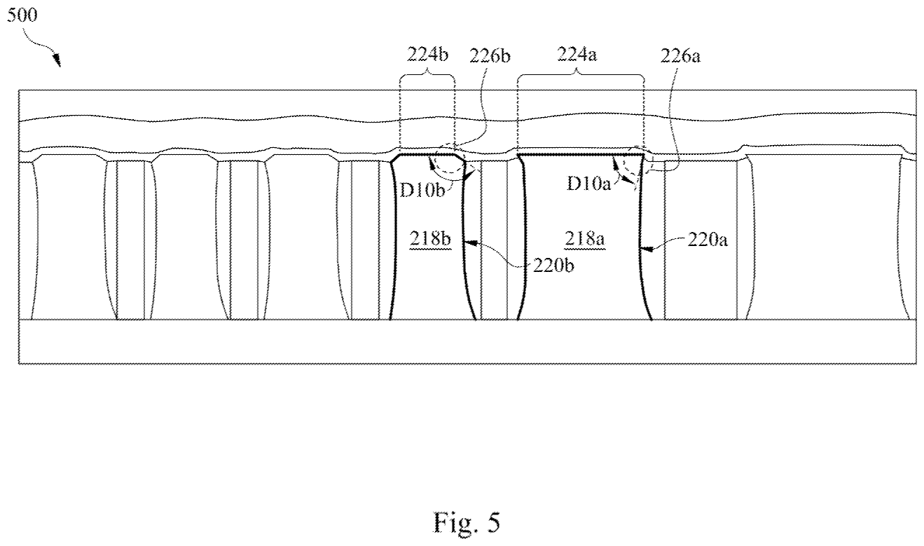

FIG. 5 is a diagram of an example implementation 500 described herein. The diagram of implementation 500 shows a view of the conductive structure(s) 218, including an angle D10 that may be associated with the sharp corner 226.

As shown in FIG. 5, the conductive structure 218a includes the vertically-oriented sidewall 220a and the approximately planar, horizontal surface 224a. The vertically-oriented sidewall 220a has a concave surface which extends inwards towards a center of the conductive structure 218a. The vertically-oriented sidewall 220a and the approximately planar, horizontal surface 224a intersect to form the sharp corner 226a. Furthermore, the sharp corner 226a includes an angle D10a, where the angle D10a is an acute angle (e.g., an angle less than approximately 90 degrees).

As further in FIG. 5, the conductive structure 218b includes the vertically-oriented sidewall 220b and the approximately planar, horizontal surface 224b. The vertically-oriented sidewall 220b has a concave surface which extends inwards towards a center of the conductive structure 218b. The vertically-oriented sidewall 220b and the approximately planar, horizontal surface 224b intersect to form the sharp corner 226b. Furthermore, the sharp corner 226b includes an angle D10b, where the angle D10b is an obtuse angle (e.g., an angle between approximately 90 degrees and approximately 180 degrees).

As such, and in some implementations, an angle D10 associated with the sharp corner 226 of the conductive structure(s) 218 may be included in a range of approximately 10 degrees to approximately 170 degrees. If the angle D10 is less than approximately 10 degrees, a thickness of the conductive structure(s) 218 across and/or proximate the approximately planar, horizontal surface 224 may be reduced and the conductive structure(s) 218 may have insufficient material for forming a robust interface with another structure (e.g., the interconnect structure(s) 228). If the angle D10 is included in the range of approximately 10 degrees to approximately 170 degrees, the conductive structure(s) 218 may be suitably formed and include sufficient material across and/or proximate the approximately planar, horizontal surface 224 to form the robust interface. Furthermore, an angle D10 that is greater than approximately 170 degrees may be indicative of the conductive structure(s) 218 being oversized (e.g., improperly formed), causing a risk of bridging and/or electrical shorting within a device (e.g., the semiconductor device 200) including the conductive structure(s) 218. However, other values and ranges for the angle D10 are within the scope of the present disclosure.

As indicated above, FIG. 5 is provided as an example. Other examples may differ from what is described with regard to FIG. 5.

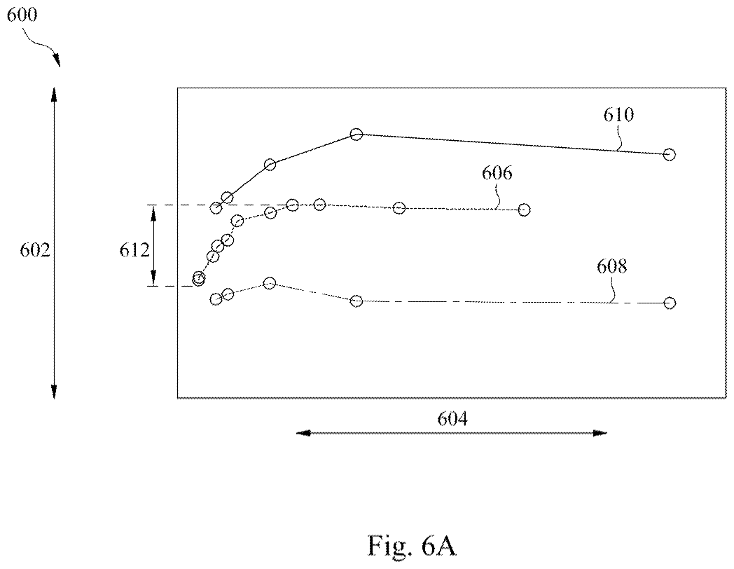

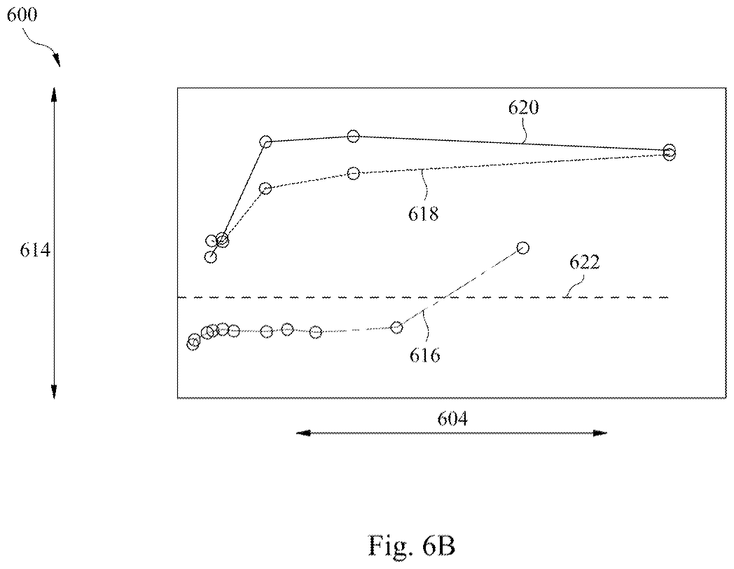

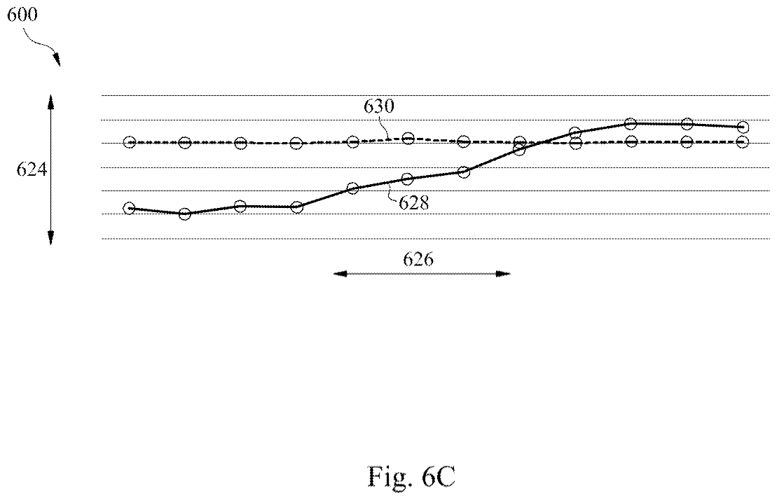

FIGS. 6A-6C are diagrams of data related to example implementations 600 of a conductive structure described herein. The conductive structure may correspond to one or more of the conductive structure(s) 218 described in connection with FIGS. 2-5.

FIG. 6A shows a relationship of height 602 of the conductive structure(s) 218 (e.g., corresponding to the height D4 as described in connection with FIG. 3B) versus width 604 of the conductive structure(s) 218 (e.g., corresponding to the width D7 as described in connection with FIG. 3C) for different combinations of RDL materials, deposition thicknesses of the RDL materials (e.g., corresponding to the height D1 as described in connection with FIG. 3A), and semiconductor technology generations (e.g., semiconductor processing technologies associated with particular semiconductor device structure and/or feature sizes).

In FIG. 6A, data 606 may correspond to an implementation of a first technology generation using a non-copper RDL material with a first nominal deposition thickness. Data 608 may correspond to an implementation of a second technology generation using a copper RDL material with the first deposition thickness, where the second technology generation is advanced relative to the first technology generation (e.g., semiconductor processing technologies associated with the second technology generation may produce structures having reduced feature sizes). Data 610 may correspond to an implementation of the second technology generation using the copper RDL material with a second deposition thickness, where the second deposition thickness is greater than the first deposition thickness.

As shown in FIG. 6A, a change 612 in the height 602 related to variations in the width 604 is more significant for a lesser range of widths. In other words, as a design or implementation of the conductive structure(s) 218 becomes “wider”, the planarization operation may become more predictable, stable, and/or repeatable. Furthermore, an implementation using the copper RDL material with the first deposition thickness (e.g., as shown by the data 608) may be more stable and experience less variation than an implementation using the copper RDL material with the second deposition thickness (e.g., as shown by the data 610).

FIG. 6B shows an example relationship related to a protrusion distance 614 of the rounded footer 222 (e.g., the distance D9 as described in connection with FIG. 3C) versus the width 604 of the conductive structure(s) 218 (e.g., the width D7 as described in connection with FIG. 3C).

In FIG. 6B, data 616 may correspond to an implementation of a first technology generation using a non-copper RDL material with a first nominal deposition thickness. Data 618 may correspond to an implementation of a second technology generation using a copper RDL material with the first deposition thickness, where the second technology generation is advanced relative to the first technology generation (e.g., semiconductor processing technologies associated with the second technology generation may produce structures having reduced feature sizes). Data 620 may correspond to an implementation of the second technology generation using the copper RDL material with a second deposition thickness, where the second deposition thickness is greater than the first deposition thickness.

FIG. 6B shows an example threshold 622 that may correspond to a radius and/or a size of the rounded footer 222. Satisfying the threshold 622 may reduce a stress concentration in the conductive structure(s). As shown in FIG. 6B, and for a smaller range of widths 604, the protrusion distance 614 associated with data 618 and 620 is substantially greater than the protrusion distance 614 associated with data 616. In other words, using the copper RDL material may increase a size and/or radius of the rounded footer 222 relative to using the non-copper RDL material.

Furthermore, the protrusion distance 614 associated with the data 618 and 620 satisfies the threshold 622 for all widths 604, whereas the protrusion distance 614 associated with the data 616 only satisfies the threshold 622 for larger widths 604. In other words, using the copper RDL material may satisfy the threshold 622 for all widths 604 to reduce a stress concentration within the conductive structure(s) 218.

FIG. 6C shows a comparison of height 624 of the conductive structure(s) 218 relative to a lateral position 626 of the conductive structure(s) 218 across the semiconductor device 200. Data 628 may correspond to the conductive structure(s) 218 being formed without planarization, and data 630 may correspond to the conductive structure(s) 218 being formed with a planarization operation as described in connection with FIG. 3B.

As shown in FIG. 6C, a variation in the height 624 associated with the data 630 is substantially less than a variation in the height associated with the data 628. In other words, a substantial within-die (WiD) improvement may be realized forming the conductive structure(s) 218 using the planarization operation described in connection with FIG. 3B.

As indicated above, FIGS. 6A-6C are provided as one or more examples. Other examples may differ from what is described with regard to FIGS. 6A-6C.

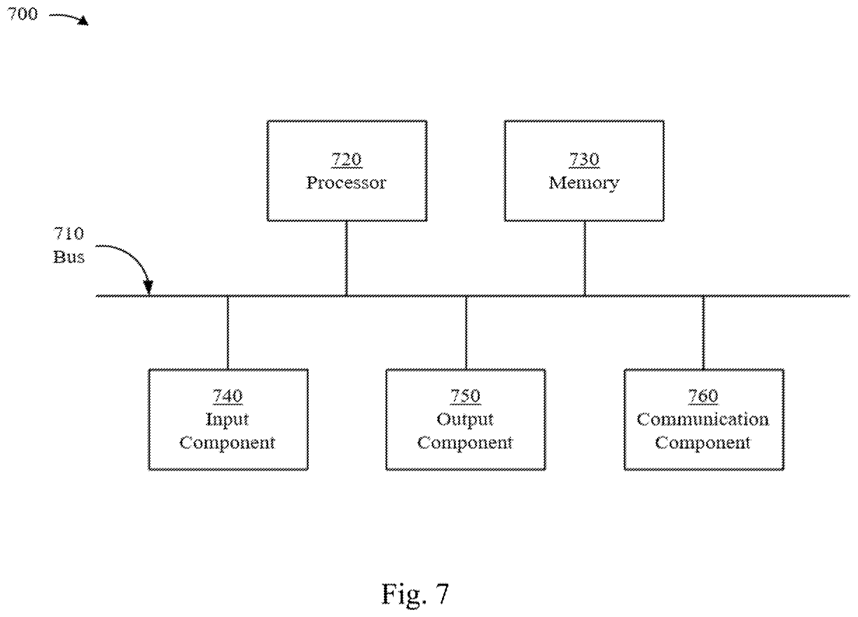

FIG. 7 is a diagram of example components one or more devices 700 described herein. The device 700 may correspond to one or more of the semiconductor processing tools 102-114 and/or the wafer/die transport tool 116 as described in connection with FIG. 1. In some implementations, one or more of the semiconductor processing tools 102-114 and/or the wafer/die transport tool 116 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

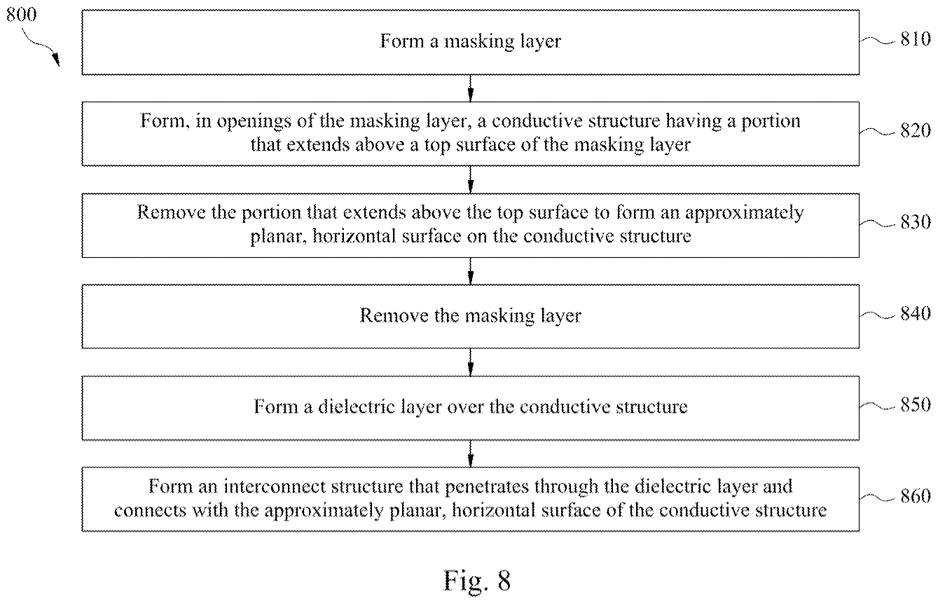

FIG. 8 is a flowchart of an example process 800 associated with forming a semiconductor device using a chemical/mechanical planarization process described herein. In some implementations, one or more process blocks of FIG. 8 are performed using one or more semiconductor processing tools (e.g., one or more of the semiconductor processing tools 102-114). Additionally, or alternatively, one or more process blocks of FIG. 8 may be performed using one or more components of device 700, such as processor 720, memory 730, input component 740, output component 750, and/or communication component 760.

As shown in FIG. 8, process 800 may include forming a masking layer (block 810). For example, one or more of the semiconductor processing tools 102-114 may be used to form a masking layer (e.g., the masking layer 302), as described herein.

As further shown in FIG. 8, process 800 may include forming, in openings of the masking layer, a conductive structure having a portion that extends above a top surface of the masking layer (block 820). For example, one or more of the semiconductor processing tools 102-114 may be used to form, in openings of the masking layer, a conductive structure (e.g., the conductive structure(s) 218) having a portion (e.g., the portion 304) that extends above a top surface of the masking layer, as described herein.

As further shown in FIG. 8, process 800 may include removing the portion that extends above the top surface to form an approximately planar, horizontal surface on the conductive structure (block 830). For example, one or more of the semiconductor processing tools 102-114 may be used to remove the portion that extends above the top surface to form an approximately planar, horizontal surface (e.g., the approximately planar, horizontal surface 224) on the conductive structure, as described herein.

As further shown in FIG. 8, process 800 may include removing the masking layer (block 840). For example, one or more of the semiconductor processing tools 102-114 may be used to remove the masking layer, as described herein.

As further shown in FIG. 8, process 800 may include forming a dielectric layer over the conductive structure (block 850). For example, one or more of the semiconductor processing tools 102-114 may be used to form a dielectric layer (e.g., the dielectric layer(s) 216) over the conductive structure, as described herein.

As further shown in FIG. 8 process 800 may include forming an interconnect structure that penetrates through the dielectric layer and connects with the approximately planar, horizontal surface of the conductive structure (block 860). For example, one or more of the semiconductor processing tools 102-114 may be used to form an interconnect structure (e.g., the interconnect structure(s) 228) that penetrates through the dielectric layer and connects with the approximately planar, horizontal surface of the conductive structure, as described herein.

Process 800 may include additional implementations, such as any single implementation or any combination of implementations described below and/or in connection with one or more other processes described elsewhere herein.

In a first implementation, forming the masking layer includes depositing a photoresist layer on a conductive layer, and forming the openings using a photolithography operation.

In a second implementation, alone or in combination with the first implementation, forming the masking layer includes depositing a hard mask layer on a conductive layer, and forming the openings using an etch operation.

In a third implementation, alone or in combination with one or more of the first and second implementations, forming the conductive structure having the portion that extends above the top surface of the masking layer includes forming a rounded footer (e.g., the rounded footer 222) that protrudes laterally from a vertically-oriented sidewall of the conductive structure at a base of the conductive structure.

In a fourth implementation, alone or in combination with one or more of the first through third implementations, removing the portion that extends above the top surface to form the approximately planar, horizontal surface includes using a chemical/mechanical planarization operation to remove the portion.

In a fifth implementation, alone or in combination with one or more of the first through fourth implementations, removing the portion to form the approximately planar, horizontal surface includes removing a portion of the masking layer.

In a sixth implementation, alone or in combination with one or more of the first through fifth implementations, removing the portion to form the approximately planar, horizontal surface includes removing the portion to form a sharp corner (e.g., the sharp corner 226) with a vertically-oriented sidewall of the conductive structure.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

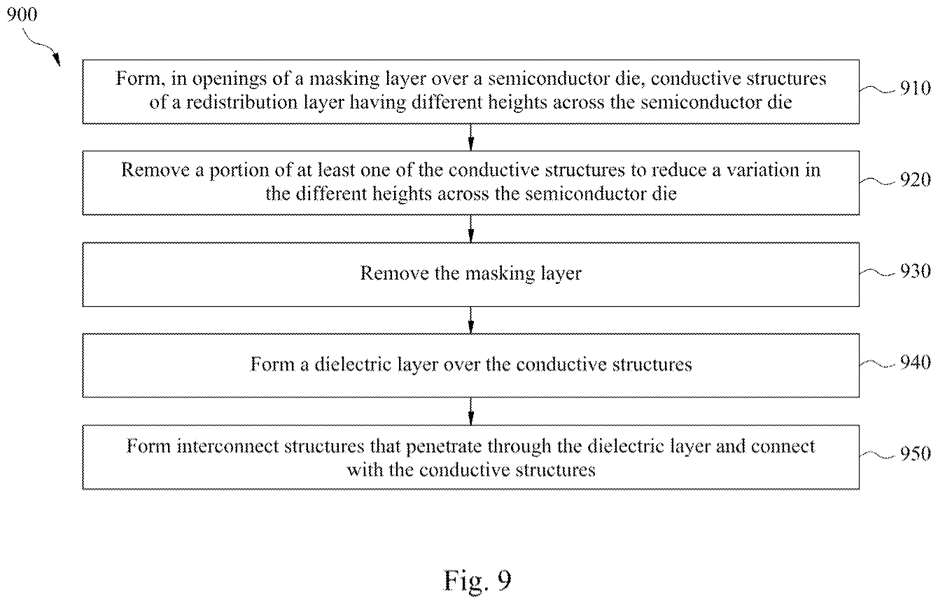

FIG. 9 is a flowchart of an example process 900 associated with forming a semiconductor device using a chemical/mechanical planarization process described herein. In some implementations, one or more process blocks of FIG. 9 are performed using one or more semiconductor processing tools (e.g., one or more of the semiconductor processing tools 102-114). Additionally, or alternatively, one or more process blocks of FIG. 9 may be performed using one or more components of device 700, such as processor 720, memory 730, input component 740, output component 750, and/or communication component 760.

As shown in FIG. 9, process 900 may include forming, in openings of a masking layer over a semiconductor die, conductive structures of a redistribution layer having different heights across the semiconductor die (block 910). For example, one or more of the semiconductor processing tools 102-114 may be used to form, in openings of a masking layer (e.g., the masking layer 302) over a semiconductor die (e.g., the semiconductor device 200), conductive structures (e.g., the conductive structure(s) 218) of a redistribution layer having different heights across the semiconductor die, as described herein.

As further shown in FIG. 9, process 900 may include removing a portion of at least one of the conductive structures to reduce a variation in the different heights across the semiconductor die (block 920). For example, one or more of the semiconductor processing tools 102-114 may be used to remove a portion of at least one of the conductive structures to reduce a variation in the different heights (e.g., the difference D3) across the semiconductor die, as described herein.

As further shown in FIG. 9, process 900 may include removing the masking layer (block 930). For example, one or more of the semiconductor processing tools 102-114 may be used to remove the masking layer, as described herein.

As further shown in FIG. 9, process 900 may include forming a dielectric layer over the conductive structures (block 940). For example, one or more of the semiconductor processing tools 102-114 may be used to form a dielectric layer (e.g., the dielectric layer(s) 216) over the conductive structures, as described herein.

As further shown in FIG. 9, process 900 may include forming interconnect structures that penetrate through the dielectric layer and connect with the conductive structures (block 950). For example, one or more of the semiconductor processing tools 102-114 may be used to form interconnect structures (e.g., the interconnect structure(s) 228) that penetrate through the dielectric layer and connect with the conductive structures, as described herein.

Process 900 may include additional implementations, such as any single implementation or any combination of implementations described below and/or in connection with one or more other processes described elsewhere herein.

In a first implementation, removing the portion of the at least one of the conductive structures to reduce the variation in the different heights improves a planarity of the conductive structures to be less than approximately 100 nanometers within the semiconductor die.

In a second implementation, alone or in combination with the first implementation, removing the portion of the at least one of the conductive structures forms at least one conductive structure having an approximately planar, horizontal surface (e.g., the approximately planar, horizontal surface 224) that intersects with a vertically-oriented sidewall (e.g., the vertically-oriented sidewall 220) wherein an intersection of the approximately planar, horizontal surface and the vertically-oriented sidewall form a sharp corner (e.g., the sharp corner 226) having an acute angle.

In a third implementation, alone or in combination with one or more of the first and second implementations, removing the portion of the at least one of the conductive structures forms at least one conductive structure having an approximately planar, horizontal surface (e.g., the approximately planar, horizontal surface 224) that intersects with a vertically-oriented sidewall (e.g., the vertically-oriented sidewall 220), wherein an intersection of the approximately planar, horizontal surface and the vertically-oriented sidewall is a sharp corner (e.g., the sharp corner 226) having an acute angle.

In a fourth implementation, alone or in combination with one or more of the first through third implementations, removing the portion of the at least one of the conductive structures to reduce the variation in the different heights includes removing the portion using a chemical/mechanical planarization operation that uses a copper slurry dispensed on a polishing pad.

In a fifth implementation, alone or in combination with one or more of the first through fourth implementations, removing the portion using the chemical/mechanical planarization operation includes stopping the chemical/mechanical planarization operation on or within the masking layer.

In a sixth implementation, alone or in combination with one or more of the first through fifth implementations, removing the portion using the chemical/mechanical planarization operation includes stopping the chemical/mechanical planarization operation above the masking layer.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

Some implementations described herein provide a semiconductor device including conductive structures formed as part of a Cu RDL. Forming the conductive structures includes forming the conductive structures in a masking structure and performing a chemical/mechanical polishing (CMP) process to planarize the conductive structures. Forming the conductive structures in the masking structure enables the conductive structures to have rounded footers and reduce stress concentrations within the semiconductor device relative to another semiconductor device using an AlCu RDL. Additionally, planarizing the conductive structures reduces a rounding of surfaces of the conductive structures that join with interconnect structures to reduce a likelihood of bonding defects.

In this way, a quality and/or a reliability of the semiconductor device is improved. By improving the quality and/or the reliability of the semiconductor device, an amount of resources used to support a market consuming the semiconductor device (e.g., raw materials, semiconductor manufacturing tools, labor, and/or computing resources) is reduced.

As described in greater detail above, some implementations described herein provide a device. The device includes a conductive structure of a redistribution layer. The conductive structure includes a vertically-oriented sidewall, a rounded footer protruding laterally from the vertically-oriented sidewall at a base of the conductive structure, and an approximately planar, horizontal surface having a sharp corner with the vertically-oriented sidewall at a top of the conductive structure that is opposite the base. The device includes an interconnect structure that connects to the conductive structure along the approximately planar, horizontal surface.

As described in greater detail above, some implementations described herein provide a method. The method includes forming a masking layer. The method includes forming, in openings of the masking layer, a conductive structure having a portion that extends above a top surface of the masking layer. The method includes removing the portion that extends above the top surface to form an approximately planar, horizontal surface on the conductive structure. The method includes removing the masking layer. The method includes forming a dielectric layer over the conductive structure. The method includes forming an interconnect structure that penetrates through the dielectric layer and connects with the approximately planar, horizontal surface of the conductive structure.

As described in greater detail above, some implementations described herein provide a method. The method includes forming, in openings of a masking layer over a semiconductor die, conductive structures of a redistribution layer having different heights across the semiconductor die. The method includes removing a portion of at least one of the conductive structures to reduce a variation in the different heights across the semiconductor die. The method includes removing the masking layer. The method includes forming a dielectric layer over the conductive structures. The method includes forming interconnect structures that penetrate through the dielectric layer and connect with the conductive structures.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a conductive structure of a redistribution layer, comprising:
a vertically-oriented sidewall,
a rounded footer protruding laterally from the vertically-oriented sidewall at a base of the conductive structure, and
an approximately planar, horizontal surface that forms a sharp corner with the vertically-oriented sidewall at a top of the conductive structure that is opposite the base; and
an interconnect structure that connects to the conductive structure along the approximately planar, horizontal surface.

2. The device of claim 1, wherein the rounded footer includes a curvature that is configured to reduce a stress concentration at the base of the conductive structure.

3. The device of claim 1, wherein the sharp corner has an angle that included in a range of approximately 10 degrees to approximately 170 degrees.

4. The device of claim 1, wherein a width of the base including the rounded footer is greater than a width of the approximately planar, horizontal surface.

5. The device of claim 1, wherein the vertically-oriented sidewall includes a concave-shaped surface that extends inwards towards a center of the conductive structure.

6. The device of claim 5, further comprising:
a dielectric layer that surrounds the conductive structure, conforms to the concave-shaped surface, and conforms to the rounded footer.

7. A method, comprising:
forming a masking layer;
forming, in openings of the masking layer, a conductive structure having a portion that extends above a top surface of the masking layer;
removing the portion that extends above the top surface to form an approximately planar, horizontal surface on the conductive structure;
removing the masking layer;
forming a dielectric layer over the conductive structure; and
forming an interconnect structure that penetrates through the dielectric layer and connects with the approximately planar, horizontal surface of the conductive structure.

8. The method of claim 7, wherein forming the masking layer includes:
depositing a photoresist layer on a conductive layer; and
forming the openings using a photolithography operation.

9. The method of claim 7, wherein forming the masking layer includes:
depositing a hard mask layer on a conductive layer; and
forming the openings using an etch operation.

10. The method of claim 7, wherein forming the conductive structure having the portion that extends above the top surface of the masking layer includes:
forming a rounded footer that protrudes laterally from a vertically-oriented sidewall of the conductive structure at a base of the conductive structure.

11. The method of claim 7, wherein removing the portion that extends above the top surface to form the approximately planar, horizontal surface includes:
using a chemical/mechanical planarization operation to remove the portion.

12. The method of claim 7, wherein removing the portion to form the approximately planar, horizontal surface includes:
removing a portion of the masking layer.

13. The method of claim 7, wherein removing the portion to form the approximately planar, horizontal surface includes:
removing the portion to form a sharp corner with a vertically-oriented sidewall of the conductive structure.

14. A method, comprising:
forming, in openings of a masking layer over a semiconductor die, conductive structures of a redistribution layer having different heights across the semiconductor die;
removing a portion of at least one of the conductive structures to reduce a variation in the different heights across the semiconductor die;
removing the masking layer;
forming a dielectric layer over the conductive structures; and
forming interconnect structures that penetrate through the dielectric layer and connect with the conductive structures.

15. The method of claim 14, wherein removing the portion of the at least one of the conductive structures to reduce the variation in the different heights improves a planarity of the conductive structures to be less than approximately 100 nanometers within the semiconductor die.

16. The method of claim 14, wherein removing the portion of the at least one of the conductive structures forms at least one conductive structure having an approximately planar, horizontal surface that intersects with a vertically-oriented sidewall,
wherein an intersection of the approximately planar, horizontal surface and the vertically-oriented sidewall form a sharp corner having an acute angle.

17. The method of claim 14, wherein removing the portion of the at least one of the conductive structures forms at least one conductive structure having an approximately planar, horizontal surface that intersects with a vertically-oriented sidewall,
wherein an intersection of the approximately planar, horizontal surface and the vertically-oriented sidewall is a sharp corner having an acute angle.

18. The method of claim 14, wherein removing the portion of the at least one of the conductive structures to reduce the variation in the different heights includes:
removing the portion using a chemical/mechanical planarization operation that uses a copper slurry dispensed on a polishing pad.

19. The method of claim 18, wherein removing the portion using the chemical/mechanical planarization operation includes:
stopping the chemical/mechanical planarization operation on or within the masking layer.

20. The method of claim 18, wherein removing the portion using the chemical/mechanical planarization operation includes:
stopping the chemical/mechanical planarization operation above the masking layer.
